(19) United States
(12) Patent Application Publication
(10) Pub. No.: US 2003/0205765 A1
(43) Pub. Date: Nov. 6, 2003

(54) Semiconductor device and method for manufacturing the same

(75) Inventor: Sadaaki Masuoka, Tokyo (JP)

Correspondence Address: YOUNG & THOMPSON, 745 SOUTH 23RD STREET 2ND FLOOR, ARLINGTON, VA, 22202

(73) Assignee: NEC CORPORATION

(21) Appl. No.: 09/822,237

(22) Filed: Apr. 2, 2001

(30) Foreign Application Priority Data
Apr. 3, 2000 (JP) 2000-101541

(51) Int. Cl. H01L 29/94

(52) U.S. Cl. 257/369

(57) ABSTRACT

A protection circuit portion comprises a CMOS to which the drain of the nMOS transistor and the pMOS transistor are connected. The drain is connected to the input or output terminal. In the nMOS transistor, the gate insulating film and the gate electrode are formed on the substrate, and the source and the drain diffusion layer are formed on the surface of the substrate at a location sandwiching the gate electrode. A P-type channel layer diffusion layer connected to the source and the drain diffusion layer is selectively formed on a lower portion of the region constituting a channel. In the pMOS, the gate insulating film, the gate electrode and the source and drain diffusion layer are formed on the well layer formed on the surface of the substrate in the same manner as the nMOS, and a channel diffusion layer is formed on the entire region of the well layer on a lower portion of the region which constitutes the channel.

### BACKGROUND OF THE INVENTION

1. Field of the Invention

The present invention relates to a semiconductor device and a method for manufacturing the same, the device being preferably used in an input and output circuit and a protection circuit or the like of the semiconductor device.

2. Description of the Prior Art

Efforts are still briskly made to make the semiconductor device such as a metal insulator semiconductor field effect transistor (hereinafter referred to as a MOS transistor) more and more fine and more highly concentrated. With respect to the increase in fineness, the MOS transistor is formed of 0.10 μm, and an investigation is made on the development of a semiconductor device of a logic device which is formed in a size of 0.10 μm wherein the size constitutes a reference of the design.

With the semiconductor device, it is indispensable to prevent a breakage of the semiconductor device (ElectroStatic Discharge: ESD) by a pulse-like high voltage or the like generated from the surplus input voltage applied from the outside instantly, for example, the electrostatic charge. Then, a protection circuit is provided between the input and output circuit connected to the outside and an internal circuit (a logic circuit or the like). The protection circuit and the input and output circuit constitute a part of the outside circuit of the semiconductor device

As a technique for protecting the semiconductor integrated circuit from such electrostatic discharge breakdown phenomenon, various ideas are proposed and used. FIG. 1 is a circuit diagram showing a typical example of thee conventional protection circuit and the input and output circuit (hereinafter referred to as a conventional example). The simplest protection circuit is, as shown in FIG. 1, such that a CMOS (a CMOS inverter) formed of a load transistor 101 and a drive transistor 102 is connected between the power source Vdd and the grounding GND. In the conventional example, the load transistor 101 is constituted of a P-channel MOS transistor (hereinafter referred to as pMOS), and the drive transistor 102 is constituted of an n-channel MOS transistor (hereinafter referred to as nMOS).

Then, an input voltage Vin is applied to Vin is applied to a drain connection point of the pMOS 101 and the nMOS 102. The protection circuit 100 is connected to a buffer circuit (input circuit) 200 so that the input voltage Vin can be applied to the gate of the buffer circuit 200. This buffer circuit 200 is also a CMOS inverter which is constituted of a pMOS 201 and an nMOS 202, so that this output is transmitted to the internal circuit. Furthermore, though not shown, the output circuit and the protection circuit are constituted of a CMOS (a CMOS inverter) as a basic circuit. The size of the CMOS which constitutes the outside circuit is extremely large as compared with the size of transistors in the internal circuit.

Next, there will be explained a conventional semiconductor device (a CMOS inverter) which constitutes the input and output circuit and a protection circuit thereof (hereinafter referred to as a protection circuit portion for the sake of convenience) of the conventional example and a method for manufacturing the same as well as a method for manufacturing the semiconductor device (CMOS) of an internal circuit portion which is formed at the same time with the protection circuit portion. FIG. 2 is a sectional view of the CMOS in the internal circuit portion. FIGS. 3A through 3D are sectional views showing a method for manufacturing the CMOS in the conventional protection circuit portion in the order of each of the steps. FIGS. 4A through 4D are sectional views showing a method for manufacturing the CMOS in the conventional internal circuit portion in the order of each of the steps. Here, FIGS. 3A through 3D are views showing the same manufacturing steps as the steps shown in FIGS. 4A through 4D.

As shown in FIG. 2, on a surface of the silicon substrate 103, device isolation films 104a and 104b are formed so that nMOS and pMOS device active regions are partitioned. On this nMOS and this pMOS device active region, the P-type lead diffusion layer 114 and the N-type lead diffusion layer 117 are formed respectively via the device isolation insulating films 104b and 104b. Hereinafter, a region including the nMOS device active region and the P-type lead diffusion layer is referred to as a nMOS region while a region including the pMOS device active region and N-type lead diffusion layer 117 is referred to as pMOS region. On the surface of the silicon substrate 103 of the nMOS region, a P-type well 105 is formed. In the entire region of the nMOS device active region in this P-type well layer 105, a P-type channel-doped layer 106a is formed which is a channel diffusion layer. In the P-type well layer 105a where the P-type lead diffusion layer 114 is formed, a P-type doped layer 106b is formed. In a similar manner, on the surface of the substrate 103 in the pMOS region, an N well layer 107 is formed. In the entire region of the pMOS device active region in this N well layer 107, an N-type channel doped layer 108a is formed which is a channel diffusion layer. In the N well layer 107a where the N-type lead diffusion layer 117 is formed, an N-type doped layer 108b is formed.

Then, at a predetermined position on the P-type channel doped layer 106a and the N-type channel doped layer 108a, a gate insulating film 109 and the gate electrode 110 are formed. On these sidewalls, a spacer (a sidewall) 111 is formed. Furthermore, on the surface of the P-type well layer 105 at a location sandwiching the gate insulating film 109 and the gate electrode 110, an N-type source diffusion layer 112 and the N-type diffusion layer 113 are formed to constitute an nMOS. Then, the P-type lead diffusion layer 114 formed by sandwiching the device isolation insulating film 104b with the N-type source diffusion layer 112 is connected to the P-type well layer 105a via the P-type doped layer 106b.

In a similar manner, at a predetermined position on the N-type channel doped layer 108a, the gate insulating film 109 and the gate electrode 110 are formed. On the sidewall thereof, a spacer 111 is formed. Furthermore, on the surface of the N well layer 107 at a location sandwiching the gate insulating film 109 and the gate electrode 110, a P-type source diffusion layer 115 and a P-type drain diffusion layer 116 are formed to constitute the pMOS. Then, the N-type lead layer 117 formed by sandwiching the device isolation insulating film 104b with the P-type source diffusion layer 115 is connected to the N well layer 107 via the N-type doped layer 108b.

In the conventional CNOS, as shown in FIG. 3, the gate electrode 110 of the nMOS, the N-type source diffusion layer 112, and the P-type lead diffusion layer 114 are connected to GND to be set to a grounding potential. Furthermore, the gate electrode 110 of the pMOS, the P-type source diffusion layer 115 and the N-type lead diffusion layer 117 are connected to Vdd to be set to the power source potential. Then, the N-type drain diffusion layer 113 of the nMOS and the P-type drain diffusion layer 116 of the pMOS are connected to become a signal line of the input or output thereby providing the voltage of Vin or Vout.

Next, there will be explained a method for manufacturing the conventional CMOS which constitutes the protection circuit and the CMOS of the internal circuit portion. Incidentally, in FIGS. 3 and 4, the same constituent elements as FIG. 2 are denoted by the same reference numerals.

As shown in FIGS. 3A and 4A, on a predetermined region on the surface of the semiconductor substrate 103 having a P-type conductive type and having an impurity concentration of about 1×10¹⁶ atoms/cm³, device isolation insulation films 104a and 104b are formed with the embedded device isolation method. Then, a resist mask 118 is formed which covers the pMOS region and opens the nMOS region and the resist mask serves as a mask for the continuous ion implantation of boron 119 twice. Energy for a first time ion implantation of boron is 150 KeV. Then energy for a second time ion implantation is about 30KeV. In the two cycles of the ion implantation and the heat treatment process after that, the P well layer 105a and the P-type channel doped layer 106a and the P-type doped layer 106b are formed at the protection circuit portion. At the same time, the P well layer 105b the P-type channel doped layer 106c and the p-type doped layer 106d of the internal circuit portion shown in FIG. 4A are formed. Here, the impurity concentration of the P well layers 105a and 105b is about 1×10¹⁷ atoms/cm³, and the impurity concentration of thee P-type channel doped layers 106 and 106b is about 5×10¹⁷ atoms/cm³.

Next, as shown in FIGS. 3B and 4B, a resist mask 120 is formed which covers the nMOS region and opens the pMOS region, thereby continuously ion implanting phosphorus and arsenic 121 by using the resist mask as a mask. Then, Energy for the first time ion implantation of arsenic is 300 kev. Then, energy for the second time ion implantation of arsenic is about 100KeV. In this manner, on the protection circuit portion shown in FIG. 3B, the N well layer 107, an N-type channel doped layer 108a, and an N-type channel doped layer 108b are formed. At the same time, on the internal circuit portion shown in FIG. 4B, the N well layer 107b, the N-type channel doped layer 108c and the N-type doped layer 108d are formed. The impurity concentration of the N well layers 107 and 107a is about 1×10¹⁷ atoms/cm³ while the impurity concentration of the N-type channel doped layers 108 and 108a is about 5×10¹⁷ atoms/cm³.

Next, as shown in FIGS. 3C and 4C, a resist mask 122 is formed which covers the entire surface of the protection circuit portion and covers the pMOS region of the internal circuit and which opens the nMOS region. Then, arsenic 124 is additionally ion implanted only to the internal circuit portion again by using the resist mask 122 as a mask. This ion implantation energy is 30KeV, and the dose amount is 7×10¹² atoms/cm². In this manner, the P-type channel doped layer 106c and the P-type doped layer 106d are formed. The impurity of this P-type channel doped layer 106b is about 1×10¹⁸ atoms/cm³.

Furthermore, as shown in FIGS. 3D and 4D, a resist mask 124 is formed which covers the entire surface of the protection circuit portion and covers nMOS region of the internal circuit portion and which open the pMOS region. Then, arsenic 125 is additionally ion implanted only to the internal circuit again by using the resist mask 124 as a mask. This ion implantation energy is 100KeV, and the dose amount thereof is 5×10¹² atoms/cm². In this manner, the N-type channel doped layer 108c and the N-type doped layer 108d of the internal circuit portion are formed. Here, the impurity concentration of the N-type channel doped layer 108c is about 1×10¹⁸ atoms/cm.

Thereafter, with a known method, as shown in FIG. 2, the gate insulating film 109 and the gate electrode 110 are formed on a predetermined region. A spacer 111 is formed on the sidewall of the gate insulating film 109 and the gate electrode 110. Furthermore, the N-type source diffusion layer 112, the N-type drain diffusion layer 113 and the P-type lead diffusion layer 114 of the nMOS are formed. The P-type source diffusion layer 115, the P-type drain diffusion layer 116 and the N-type lead diffusion layer 117 of the pMOS are formed. Incidentally, in the CMOS in the inside of the internal circuit portion, the thickness of the gate insulating film becomes thin to about ⅓ of the thickness of gate insulating film of the protection circuit portion. Then, the gate length of the MOS transistor which constitutes the internal circuit portion is about ⅓ of the protection circuit portion.

In the CMOS having a design size of 0.1 μm, the thickness of the gate insulating film of the internal circuit potion is 2 nm in terms of the thickness of the silicon oxide film and the gate length is about 0.1 μm. Then, the thickness of the gate insulating film of the protection circuit portion is about 6 nm in terms of the thickness of the silicon oxide film, and the gate length is about 0.3 μm.

Here, the depth of the P well layers 105a and 105b, the N well layers 107a and 107b is about 0.5 μm. The depth of the P-type channel doped layer 106a and the N-type channel doped layer 108a is about 0.15 μm. Then, the depth of the source and drain diffusion layer and the lead diffusion layer is about 0.1 μm.

As described above, in recent years, the semiconductor device becomes highly integrated and heightened in speed. As a consequence, each of the semiconductor elements such as the individual MOS transistors which constitute the semiconductor device become more and more fine and more and more highly integrated. When the semiconductor device is made fine in this manner, failure of the semiconductor device generally resulting from the ESD is caused many times. Furthermore, it is indispensable to lower the consumed power for the semiconductor device, and the voltage drop at the time of operation becomes important. However, when the voltage is lowered in this manner, the semiconductor device which constitutes the internal circuit are more likely to be damaged than the prior art in the case where the amount of the electrostatic charge is small, and a surplus input voltage is small.

In such trends of technology, the development of technology for protecting the semiconductor device from the ESD or the like becomes more urgent than ever before.

Furthermore, in accordance with the increase in the fineness of the semiconductor device, it becomes effective to decrease the resistance of the semiconductor substrate in a region deeper than the region which forms the source and drain diffusion layer for suppressing a latch-up of the CMOS which constitutes the internal circuit portion while keeping the impurity concentration of the region which forms the source and drain diffusion layer in order to reduce the parasitic capacity of the source and drain diffusion layer of the internal circuit low. As a method for lowering the resistance of the semiconductor substrate, for example, P/P⁺ substrate is used. However, the details thereof will be described later. When the P/P substrate is replaced with the P/P⁺ substrate, there arises a problem in that the MOS transistor of the protection circuit portion ceases to cause a snap back so that the protection circuit ceases to function.

Furthermore, in the prior art, it is constituted that the highly concentrated P(N)-type channel doped layer and the source and drain diffusion layer of the MOS transistor are overlapped on the entire surface. Consequently, a junction capacity between the input and output circuit and the channel doped layer (channel diffusion layer) increases. This leads to a problem in that particularly an increase in the consumed power and a decrease in the operation speed become conspicuous of the input and output circuit or the protection circuit.

### SUMMARY OF THE INVENTION

The object of the present invention is to provide a semiconductor device and a method for manufacturing the same which can protect the semiconductor device from the phenomenon of electrostatic discharge breakdown with a simple method, and which can facilitate the improvement in the operation speed and the decrease of the consumed power of the input and output circuit or the protection circuit portion.

A semiconductor device according a first aspect of the present invention comprises:

a semiconductor substrate;

a gate insulating film formed at a predetermined portion on the semiconductor substrate and a gate electrode formed on the gate insulating film;

source and drain diffusion layers formed at the surface of the semiconductor substrate at portions sandwiching a channel region under the gate electrode; and

a channel diffusion layer having a conductive type reverse to the source and drain diffusion layers and a higher impurity concentration than the semiconductor substrate, the channel diffusion layer being selectively formed at a lower portion of the channel region to be connected to the source and drain diffusion layers.

A semiconductor device according a second aspect of the present invention comprises:

a semiconductor substrate;

an epitaxial layer having the same conductive type as the semiconductor substrate and a lower impurity concentration than the semiconductor substrate, the layer being formed on the semiconductor substrate;

a gate insulating film formed at a predetermined portion on the epitaxial layer, and a gate electrode formed on the gate insulating film;

source and drain diffusion layers formed at the surface of the epitaxial layer at portions sandwiching a channel region under the gate electrode; and

a channel diffusion layer having a conductive type reverse to the source and drain diffusion layers and a higher impurity concentration than the epitaxial layer, the channel diffusion layer being selectively formed at a lower portion of the channel region to be connected to the source and drain diffusion layers.

A semiconductor device according a third aspect of the present invention comprises:

a semiconductor substrate;

a well layer having a conductive type reverse to the semiconductor substrate, the layer being formed on the surface of the semiconductor substrate;

a gate insulating film formed at a predetermined portion on the well layer and a gate electrode formed on the gate insulating film;

source and drain diffusion layers formed at the surface of the well layer at portions sandwiching a channel region under the gate electrode; and

a channel diffusion layer having a conductive type reverse to the source and drain diffusion layers and a higher impurity concentration than the well layer, the channel diffusion layer being selectively formed at a lower portion of the channel region to be connected to the source and drain regions.

Incidentally, a well layer may be formed on the surface of the epitaxial layer of the semiconductor device according to the second aspect of the invention.

A semiconductor device according a fourth aspect of the present invention comprises:

a semiconductor substrate of a first conductive type;

a well layer of a second conductive type selectively formed on the surface of the semiconductor substrate;

a first gate insulating film formed at a predetermined portion on the semiconductor substrate and a first gate electrode formed on the first gate insulating film;

a second gate insulating film formed at a predetermined portion on the well layer and a second gate electrode formed on the second gate insulating film;

first source and drain diffusion layers of a first conductive type formed at the surface of the semiconductor substrate at portions sandwiching a channel region under the first gate electrode;

second source and drain diffusion layers of a second conductive type formed at the surface of the well layer at portions sandwiching a channel region under the second gate electrode;

a first channel diffusion layer of a second conductive type having a higher impurity concentration than the semiconductor substrate, the first channel diffusion layer being selectively formed at a lower portion of the channel region to be connected to the first source and drain diffusion layers; and

a second channel diffusion layer of a first conductive type having a higher impurity concentration than the well layer, the second channel diffusion layer being formed at an entire region between the second source and drain diffusion layers so as to be connected to the second source and drain diffusion layers at a lower portion of the channel region.

A semiconductor device according a fifth aspect of the present invention comprises:

a semiconductor substrate of a first conductive type;

a well layer of a second conductive type selectively formed on the surface of the semiconductor substrate;

a first gate insulating film formed at a predetermined portion on the semiconductor substrate and a first gate electrode formed on the first gate insulating film;

a second gate insulating film formed at a predetermined portion on the well layer and a second gate electrode formed on the second gate insulating film;

first source and drain diffusion layers of a first conductive type formed at the surface of the semiconductor substrate at portions sandwiching a channel region under the first gate electrode;

second source and drain diffusion layers of a second conductive type formed at the surface of the well layer at portions sandwiching a channel region under the second gate electrode;

a first channel diffusion layer of a second conductive type having a higher impurity concentration than the semiconductor substrate, the first channel diffusion layer being selectively formed at a lower portion of the channel region to be connected to the first source and drain diffusion layers; and

a second channel diffusion layer of a first conductive type having a higher impurity concentration than the well layer, the second channel diffusion layer being selectively formed at a lower portion of the channel region to be connected to the second source and drain diffusion layers.

According to the first to the fifth aspects of the present invention, the channel diffusion layer of the semiconductor device is selectively formed between the source diffusion layer and the drain diffusion layer. Consequently, even when the impurity concentration in the silicon substrate becomes high as a result of higher integration and higher speed of the semiconductor device, the MOS transistor itself comes to have a snap back effect while the junction capacity between the drain diffusion layer and the substrate is largely decreased, and consumed power of the large capacity input and output circuit or the protection circuit portion is decreased so the operation speed can be improved.

Furthermore, in accordance with the fourth and the fifth semiconductor device, when the semiconductor integrated circuit is used in the input and output circuit or the protection circuit portion, the ESD tolerance voltage can be improved even with the higher integration and the higher speed of the semiconductor device. Furthermore, since the electrostatic discharge protection device can be easily operated at a low voltage, the voltage of the semiconductor device can be easily lowered. Incidentally, in the case where the fourth and the fifth semiconductor device is used in the CMOS inverter of the protection circuit, for example, the first conductive type is formed of P-type, and the second conductive type is formed of N-type while the first MOS transistor and the second MOS transistor are formed of nMOS and pMOS respectively. Then, the P-type lead diffusion layer and the N-type diffusion layer are provided via the source diffusion layer and the device isolation insulating film of the nMOS and pMOS. Then, the drain diffusion layer of the nMOS and the pMOS is connected thereto and is connected to the input and output terminal, so that the gate electrode, the source diffusion layer and the lead diffusion layer are connected to be connected to the grounding.

A method for manufacturing a semiconductor device according the first aspect of to the present invention, comprises the steps of:

forming a channel diffusion layer having a higher impurity concentration than the semiconductor substrate on a lower portion of a region which constitutes a channel by selectively ion implanting a first conductive type of impurity between a region where a source diffusion layer on the first conductive type semiconductor substrate is to be formed and a region where a drain diffusion layer is to be formed thereon;

subsequently forming a gate insulating film and a gate electrode on the semiconductor substrate above the channel diffusion layer; and

forming a source diffusion layer and a drain diffusion layer by ion implanting a second conductive type of impurity on the surface of the semiconductor substrate at a location sandwiching the gate electrode.

A method for manufacturing a semiconductor device according to the second aspect of the present invention, comprises the steps of:

forming a well layer by ion implanting a second conductive type of impurity on the surface of the first conductive type of the semiconductor substrate;

forming a channel diffusion layer having a higher impurity concentration than the well layer at a lower portion of the region which constitutes a channel by the selective ion implantation of the second conductive type of impurity between a region where the source diffusion layer of the well layer is to be formed and a region where a drain diffusion layer is to be formed thereon;

subsequently forming a gate insulating film on the well above the channel diffusion layer and a gate electrode on the gate insulating film; and

forming a source diffusion layer and a drain diffusion layer by the ion implantation of the first conductive type of impurity on the surface of the well layer at a location sandwiching the gate electrode.

A method for manufacturing a semiconductor device according to the third aspect of the present invention, comprises the steps of;

forming the well layer and a channel diffusion layer having a higher impurity concentration than the well layer on the entire well layer at the lower portion of the region which constitutes a channel of the first MOS transistor by selectively ion implanting a plurality of times a second conductive type of impurity on the first MOS transistor formation region on the surface of the first conductive type semiconductor substrate;

forming a channel diffusion layer having a higher impurity concentration than the semiconductor substrate on a lower portion of the region which constitutes a channel of the second MOS transistor by selectively ion implanting the first conductive type of impurity between the region where the source of the second MOS transistor formation region is to be formed on the surface of the semiconductor substrate and the region where the drain diffusion layer is to be formed;

subsequently forming a gate insulating film of the first MOS transistor and the second MOS transistor and a gate electrode on the gate insulating film respectively on the well layer of the region which constitutes a channel of the first MOS transistor and the second MOS transistor and on the semiconductor substrate;

forming the source diffusion layer and the drain diffusion layer of the first MOS transistor by ion implanting the first conductive type of impurity on the surface of the well layer at a location sandwiching the gate electrode of the first MOS transistor; and

forming the source diffusion layer and the drain diffusion layer of the second MOS transistor by ion implanting the second conductive type of impurity on the surface of the semiconductor substrate at a location sandwiching the gate electrode of the second MOS transistor.

### BRIEF DESCRIPTION OF THE DRAWINGS

FIG. 1 is a circuit diagram showing a typical example of a conventional protection circuit portion and an input and output circuit;

FIG. 2 is a sectional view showing a CMOS inverter of the protection portion;

FIGS. 3A through 3B are sectional views showing a method for manufacturing a CMOS inverter of the conventional protection circuit portion in order of steps;

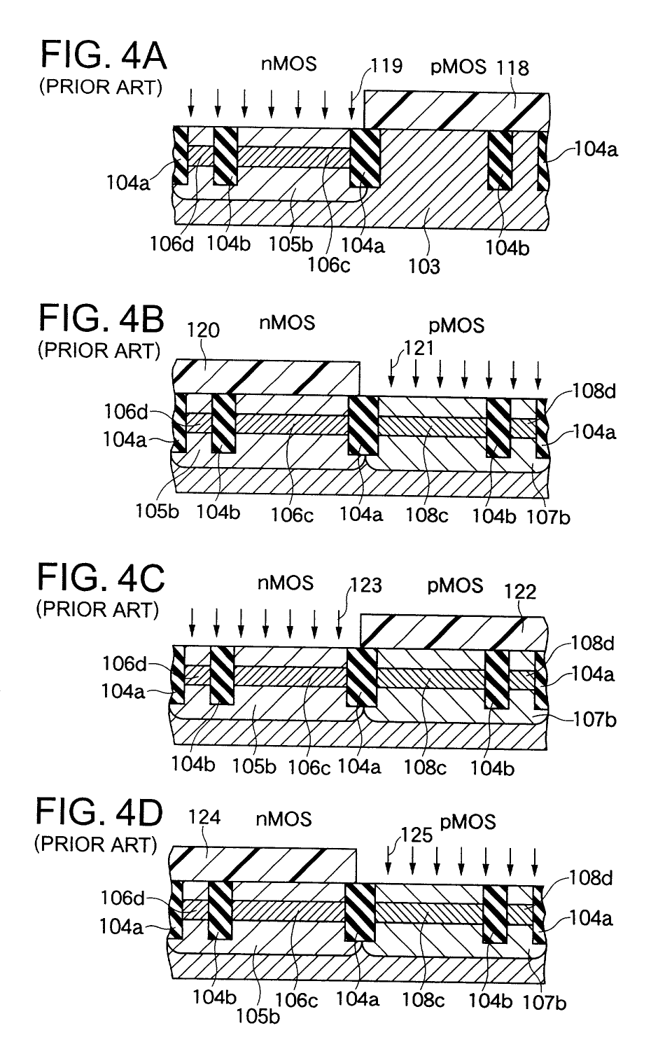

FIGS. 4A through 4D are sectional views showing a method for manufacturing the CMOS of the conventional internal circuit portion in the order of steps;

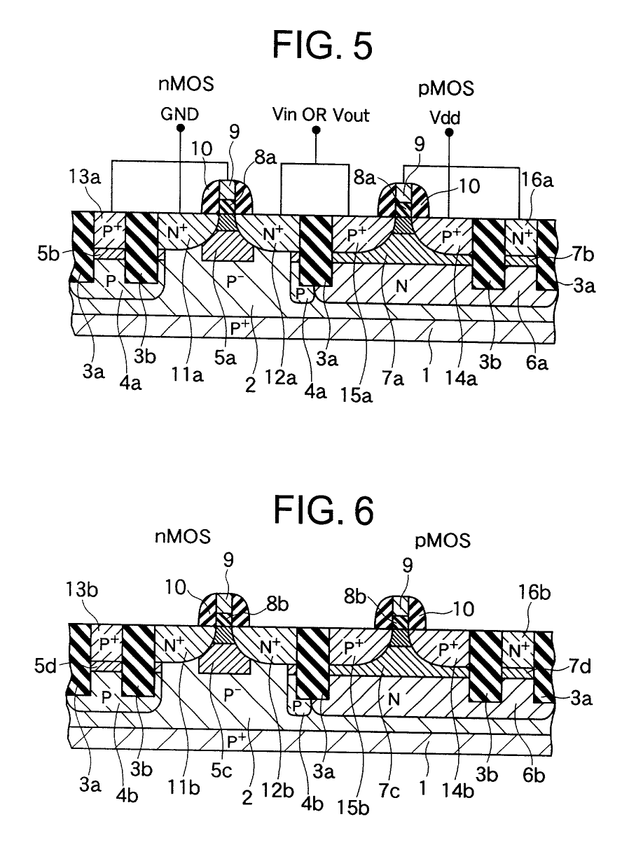

FIG. 5 is a sectional view showing a semiconductor device (CMOS inverter of the protection circuit portion) according to a first embodiment;

FIG. 6 is a sectional view showing a semiconductor device (CMOS of the internal circuit portion) of the semiconductor device according to a first embodiment of the present invention;

FIGS. 7A through 7B are sectional views showing a method for manufacturing the CMOS transistor of the protection circuit portion according to a first embodiment of the present invention;

FIGS. 8A through 8E are sectional views showing a method for manufacturing a CMOS of the internal circuit portion according to a first embodiment of the present invention;

FIG. 9A is a graph showing a reverse tolerance voltage characteristic by taking a voltage between the source and drain of an nMOS on a horizontal axis and taking a current between the source and drain on the vertical axis thereof; FIGS. 9B and 9C are sectional views showing a semiconductor device according a first embodiment and a prior art of the present invention wherein a tolerance voltage property is measured;

FIG. 10 is a sectional view showing a CMOS of the internal circuit portion according to a second embodiment of the present invention;

FIGS. 11A through 11D are sectional views showing a method for manufacturing a semiconductor device (a CMOS inverter of the protection circuit portion) according to the second embodiment of the present invention in order of steps;

FIGS. 12A through 12D are sectional views showing a method for manufacturing the CMOS of the internal circuit portion according to the second embodiment of the present invention in order of steps;

FIG. 13 is a sectional view showing a semiconductor device (a CMOS inverter of the protection circuit portion) according to the third embodiment of the present invention;

FIGS. 14A through 14D are sectional views showing a method for manufacturing a CMOS inverter of the protection circuit portion according a third embodiment of the present invention in order of steps; and

FIG. 15 is a graph showing a parasitic capacity of a junction between the N-type drain diffusion layer and the substrate in the nMOS of the protection circuit portion according to a third embodiment of the present invention by taking a reverse bias applied between the drain diffusion layer and a substrate on the horizontal axis and taking a junction capacity on the vertical axis;

### DETAILED DESCRIPTION OF THE PREFERRED EMBODIMENT

Hereinafter, embodiments of the present invention will be specifically explained by referring to the accompanied drawings.

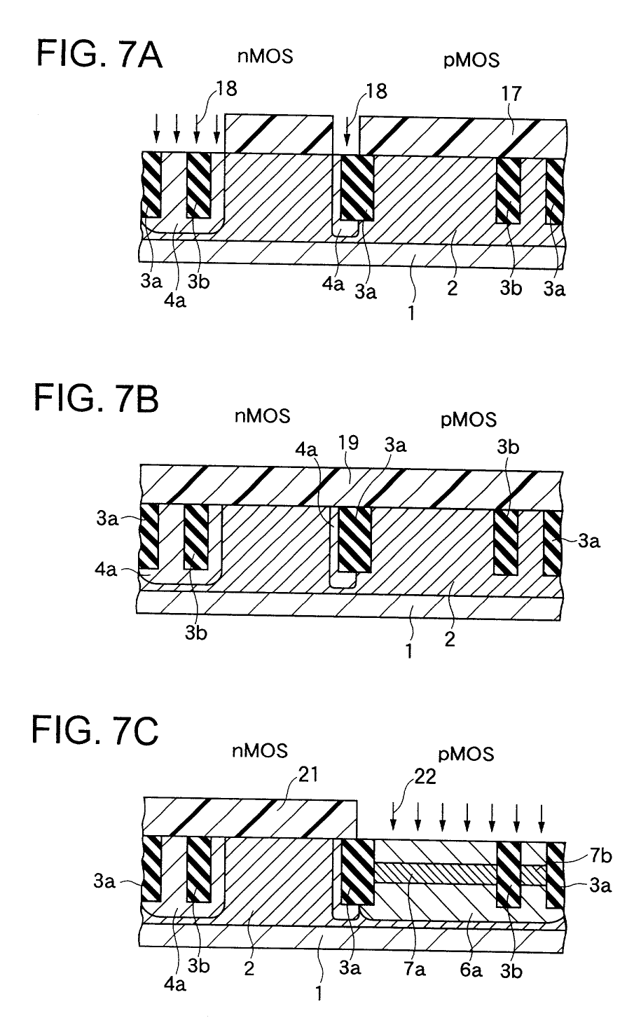

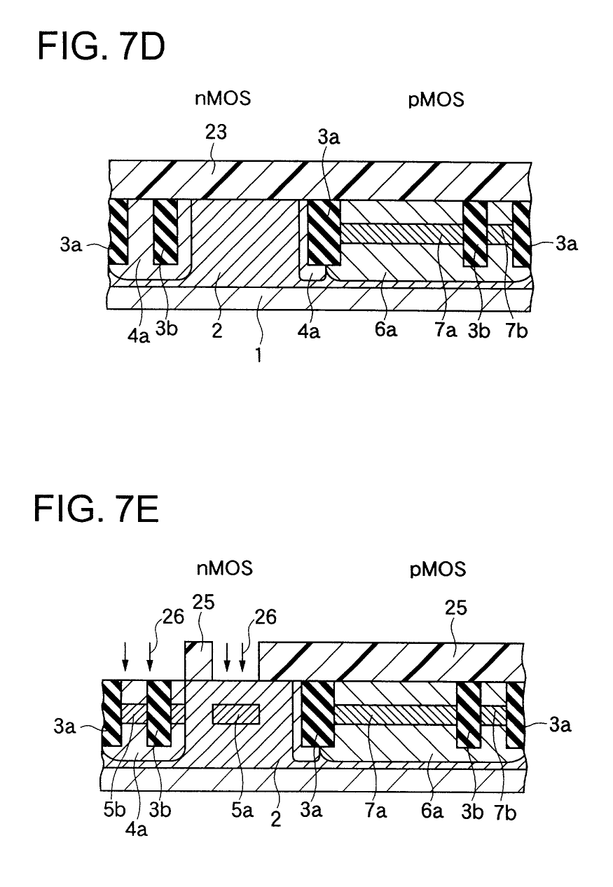

FIGS. 5 and 6 are sectional views showing a semiconductor device according to a first embodiment of the present invention. FIG. 5 is a view showing a CMOS inverter which constitutes a protection circuit portion. FIG. 6 is a view showing a CMOS which constitutes the internal circuit portion.

In the CMOS inverter of the protection circuit portion, as shown in FIG. 5, a silicon epitaxial layer 2 having a thickness of 3 μm is formed on a P-conductive type high concentration silicon base 1 having an impurity concentration of 10¹⁸ through 10¹⁹ atoms/cm³. The conductive type of this silicon epitaxial layer 2 is P-type, and the impurity concentration thereof is about 1×10¹⁵ atoms/cm³, and the impurity concentration is lower than the silicon substrate 1. Then, on the surface of the silicon epitaxial layer 2, device isolation insulating films 3a and 3b are formed. The nMOS device active region and the pMOS device region are partitioned. On the nMOS device active region and the pMOS device region, the P-type lead diffusion layer 13a and the N-type lead diffusion layer 16b are formed respectively via the device isolation insulating films 3a and 3b. Then, a P-well layer 4a is formed on the entire region of the lower portion of the P-type lead diffusion layer 13a from the vicinity of the device isolation insulating film 3a partitioning the nMOS transistor in the nMOS active region and the pMOS transistor and from the vicinity of the device separation insulating film 3b.

Then, the P-type locally doped layer 5 characterizing the present invention is selectively formed in a region located at a lower portion of the nMOS channel region in the above silicon epitaxial layer 2. This P-type locally doped layer 5 is the nMOS channel diffusion layer.

Furthermore, on the surface of the epitaxial layer 2 of the pMOS region including the pMOS device active region and the N-type lead diffusion layer, an N-well layer 6 is formed. Furthermore, in the N-well layer 6, an N-type channel doped layer 7 is formed in the entire region of the N-well layer of the lower portion of the channel region.

The other structure is the same as the CMOS of the prior art described above. In the nMOS device active region, the gate insulating film 8a and the gate electrode 9 are formed on a predetermined region on the epitaxial layer 2. On the sidewall of the gate insulating film 8a and the gate electrode 9, a spacer 10 is formed. Furthermore, on the surface of the epitaxial layer 2 at a position sandwiching the gate insulating film 8a and the gate electrode 9, N-type source and diffusion layer 11a and N-type drain diffusion layer 12a are formed. The P-type channel doped layer 5a is connected to the N-type source diffusion layer 11a and the N-type drain diffusion layer 12a at both end portions of the layer 5a. Thus, the nMOS is constituted. Furthermore, the P-type lead diffusion layer 13a is connected to the P-well layer 4 via the P-type locally doped layer 5b. Hereinafter, a region including the nMOS device active region and the P-type lead diffusion layer is referred to as the nMOS region.

Furthermore, in the pMOS device active region, the gate insulating film 8a and the gate electrode 9 are formed on a predetermined region on the well layer 6a. On the sidewall of the gate insulating film 8a and the gate electrode 9, the spacer 10 is formed. Furthermore, on the surface of the well layer 6a at a position sandwiching the gate insulating film 8a and the gate electrode 9, the P-type source diffusion layer 14a and the P-type drain diffusion layer 15a are formed. Then, the N-type channel doped layer 7a formed on the entire surface of the well layer 6a is connected at the lower end of the N-type source diffusion layer 11a and the N-type drain diffusion layer 12a. Thus, the pMOS is constituted. Furthermore, the N-type lead diffusion layer 16a is connected to the P well layer 4 via the N-type doped layer 7b. Hereinafter, a region including the pMOS device active region and the N-type lead diffusion layer a is referred to as a pMOS region.

Then, in the CMOS inverter, as shown in FIG. 5, the nMOS gate electrode 9, the N-type source diffusion layer 11 and the P-type lead diffusion layer 13 are connected to GND. The gate electrode 9 of the pMOS, the P-type source diffusion layer 14 and the N-type lead diffusion layer 16 are connected to the Vdd. Then, the N-type drain diffusion layer 12 of the nMOS and the P-type drain diffusion layer 15 of the pMOS are connected to form an input or output signal line and a voltage of Vin or Vout.

The CMOS of the internal circuit portion, as shown in FIG. 6, has the same structure as the protection circuit portion shown in FIG. 5. However, the actual size of the CMOS is considerably smaller than the protection circuit portion shown in FIG. 5. Incidentally, in FIG. 6, for facilitating a comparison with FIG. 5, the size is set to the same level as in FIG. 5. Furthermore, the same constituent elements as FIG. 5 are denoted by the same reference numeral and detailed explanation thereof is omitted.

In the same manner as FIG. 5, as shown in FIG. 6, a silicon epitaxial layer 2 is formed on the high concentration silicon substrate 1. On the surface of the silicon epitaxial layer 2, the device isolation insulation films 3a and 3b are formed, so that the device active regions of nMOS and pMOS are partitioned.

Then, in the internal circuit portion as well, in the same manner as the above protection circuit portion, the well layer 4b is formed on a portion of the nMOS device active region, and the P-type locally doped layer 5c is selectively formed on the region located on a lower portion of the channel region. Besides, on the nMOS device active region, the N well layer 6b is formed, and N-type channel doped layer 7c is formed in a band-like configuration in the entire region of the inside of the N well layer 6b.

On a predetermined region of the nMOS region of the silicon substrate 1 which is constituted in this manner, the gate insulating film 8b and the gate electrode 9 are formed, and the spacer 10 is formed on the sidewall of the gate insulating film 8b and the gate electrode 9. Furthermore, on the surface of the epitaxial layer 2, the N-type source diffusion layer 11b and the N-type drain diffusion layer 12b are formed at a location sandwiching the gate insulating film 8b and the gate electrode 9. In this manner, the nMOS transistor of the internal circuit portion is formed. Furthermore, the P-type lead diffusion layer 13b is formed via the device isolation insulating film 3b on the N-type source diffusion layer 11b. This P-type lead diffusion layer 13b is connected to the P well layer 4b via the P-type doped layer 5d.

Furthermore, on a predetermined region of the nMOS device region as well, the gate insulating film 8b, the gate electrode 9 and the spacer 10 are formed, and on the well layer 6b, P-type source diffusion layer 14b and P-type drain diffusion layer 15b are formed at the location sandwiching the gate insulating film 8b and the gate electrode 9. The pMOS transistor of CMOS of the internal circuit are constructed in this way. In addition, the N-type lad diffusion layer 16b is provided via the device isolating insulating film 3b on the P-type source diffusion layer 14b. This N-type lead diffusion layer 16b is connected to the N-well layer 6b via the N-type doped layer 7d.

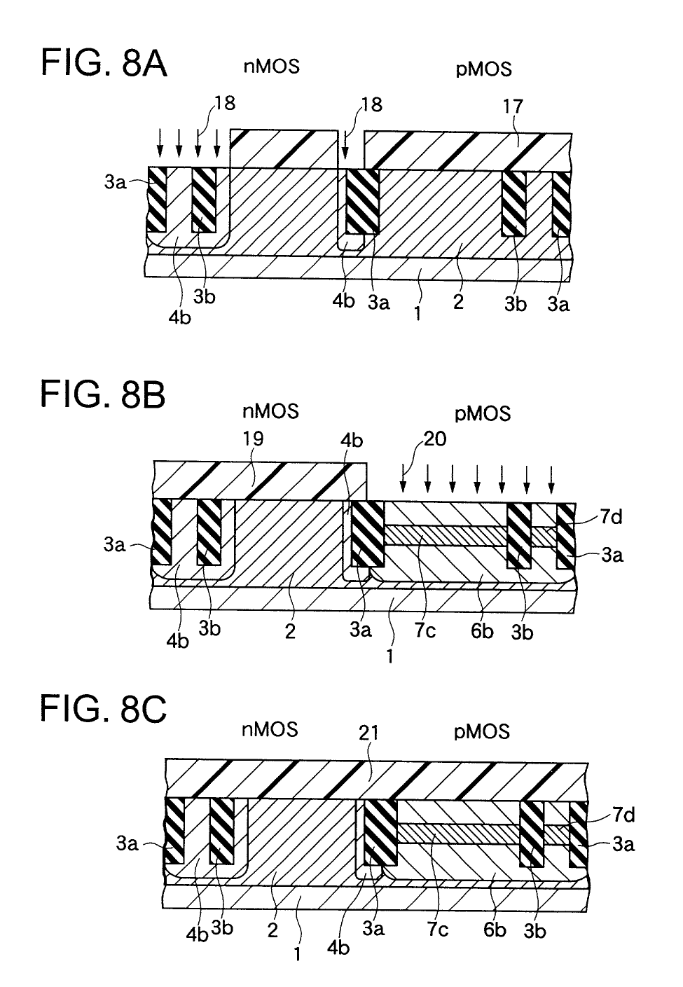

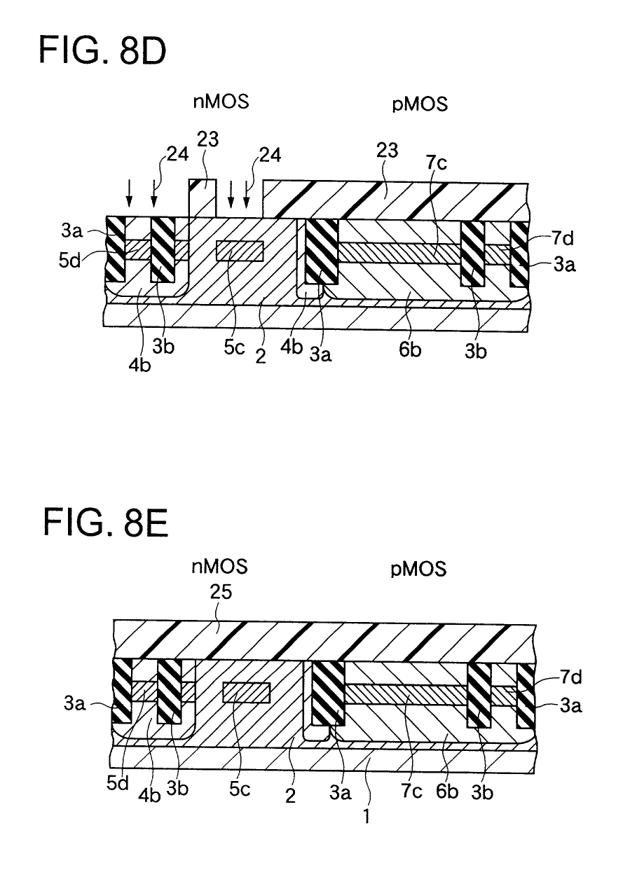

FIGS. 7A through 7E are sectional views showing a method for manufacturing the CMOS inverter of the protection circuit portion. FIGS. 8A through 8E are sectional views showing a method for manufacturing the CMOS of the internal circuit of the first embodiment in the order of steps thereof. Incidentally, the manufacturing process shown in FIGS. 7A through 7E are the same as the manufacturing process shown in FIGS. 8A through 8E. Besides, the same constituent elements as FIGS. 5 and 6 are denoted by the same reference numerals.

As shown in FIGS. 7A and 8A, the silicon epitaxial layer 2 having a thickness of 3 μm is formed on the P-type conductive type of the high concentration silicon substrate 1 having an impurity concentration of 1×10¹⁹ atoms/cm³. The impurity concentration of the silicon epitaxial layer 2 is about 1×10¹⁵ atoms/cm³. In this manner, P/P⁺ silicon substrate is formed.

Next, on a predetermined region of the surface of the silicon epitaxial layer 2, device isolation insulating films 3a and 3b are formed with the known trench device isolation technology. Then, a portion of the nMOS device active region of the protection circuit and the internal circuit is opened, and a resist mask 17 is formed so that boron 18 is ion implanted by using the mask 17 as a mask. In the ion implantation, implantation energy is set to a level of 150 KeV while the dose amount is set to about 2×10¹³ atoms/cm². Therefore, the P-well layer 4 is formed on a part of nMOS region. With this P-well layer 4, a channel stopper region is formed under the device isolation insulating films 3a, 3b.

Next, as shown in FIGS. 7B and 8B, the entire surface of the protection circuit portion is covered while the nMOS region of the internal circuit portion is covered to form a resist mask 19 in which the pMOS region is open. Then, as shown in FIG. 8B, phosphorus or arsenic 20 is ion implanted by using the resist mask 19 is used as a mask. In the beginning, as a first time ion implantation, phosphorus is ion implanted. The implantation energy of phosphorus is, for example, 300KeV while the dose amount is, for example, 1×10¹³ atoms/cm². Then, as the second time ion implantation, arsenic is continuously ion implanted. This arsenic ion implantation energy is, for example, 100KeV while the dose amount is, for example, 7×10¹² atoms/cm². Next, heat treatment is conducted. In this manner, on the internal circuit portion the N well layer 6b, the N-type channel doped layer 7c, and the N-type doped layer 7d are formed.

In the case of the embodiment, the impurity concentration of the N well layer 6b is about 1×10¹⁷ atoms/cm³ while the impurity concentration of the N-type channel doped layer 7c and the N-type doped layer 7d is about 1×10¹⁸ atoms/cm³.

In a similar manner, as shown in FIGS. 7C and 8C, the entire surface of the internal circuit is covered and the nMOS region of the protection circuit portion is covered so the resist mask 21 is formed in which pMOS region is open. In a similar manner as the internal circuit, phosphorus and arsenic 22 are continuously ion implanted into the internal circuit and the protection circuit portion. As a consequence, as shown in FIG. 7C, the N well layer 6a, the N-type channel doped layer 7a, and the N-type doped layer 7b are formed on the protection circuit portion. In the case of the embodiment, the impurity concentration of the N well layer 6a is about 1×10¹⁷ atoms/cm³, and the impurity concentration of the N-type channel doped layer 7a and the N-type doped layer 7b is about 5×10¹⁷ atoms/cm³.

Next, as shown in FIGS. 7D and 8D, the entire surface of the protection circuit portion is covered, so that a resist mask 23 is formed wherein the channel region and the lead diffusion region of the internal circuit portion are open. Then boron 24 is ion implanted by using the resist mask 23 as a mask. This ion implantation energy is, for example, 30KeV, and the dose amount is, for example, about 1×10¹³ atoms/cm². Thereafter, by heat treatment, as shown in FIG. 8D, the P-type locally doped layer 5c which is a channel diffusion layer is selectively formed on a region located at a lower portion of the nMOS channel region in the silicon epitaxial layer 2. Furthermore, at the same time, boron is ion implanted also into the surface of the P well layer 4b of the lead diffusion layer formation region to form the P-type doped layer 5d in the P-well well layer 4b. Incidentally, as shown in FIG. 7D, boron is not ion implanted into the protection circuit portion.

Next, as shown in FIGS. 7E and 8E, the entire surface of the internal circuit portion is covered, so that the resist mask 25 is formed in which the channel region and the lead diffusion layer formation region of the protection circuit portion are open. Then boron 26 is ion implanted by using the resist mask 25 as a mask. This ion implantation energy is, for example, about 30KeV, and the dose amount is, for example, about 6×10¹² atoms/cm². Next, by heat treatment, on a region located on a lower portion of the nMOS region in the silicon epitaxial layer 2 of the protection circuit portion, the p-type locally doped layer 5a is selectively formed which constitutes a channel diffusion layer. Furthermore, at the same time, boron is also ion implanted into the surface of the P well layer 4a of the lead diffusion layer formation region, so the P-type doped layer 5b is formed inside of the P well layer 4.

Thereafter, in the conventional known method, as shown in FIGS. 5 and 6 the gate insulating films 8a and 8b, the gate electrode 9, and the spacer 10 are formed. Furthermore, the CMOS is formed by providing the source and drain diffusion layer and the lead diffusion layer of the nMOS and pMOS source and drain diffusion layer and the lead diffusion layer.

Here, the thickness of the gate insulating film 8b of the internal circuit portion is, for example, about 2 nm in terms of the silicon oxide film while the gate length thereof is, for example, about 0.1 μm. On the other hand, the thickness of the gate insulating film 8a of the protection circuit portion is, for example, about 6 nm in terms of the silicon oxide film while the gate length thereof is, for example, 0.3 μm.

Besides, the depth of the P-type doped layers 5a and 5b is, for example, 0.15 μm. Furthermore, the depth of the N well layer 6a and 6b is, for example, about 0.5 μm while the depth of the N-type channel doped layer 7a and 7b is, for example, about 0.15 μm. Then, the depth of the nMOS and pMOS source and drain diffusion layers, and the lead diffusion layer is, for example, about 0.1 μm.

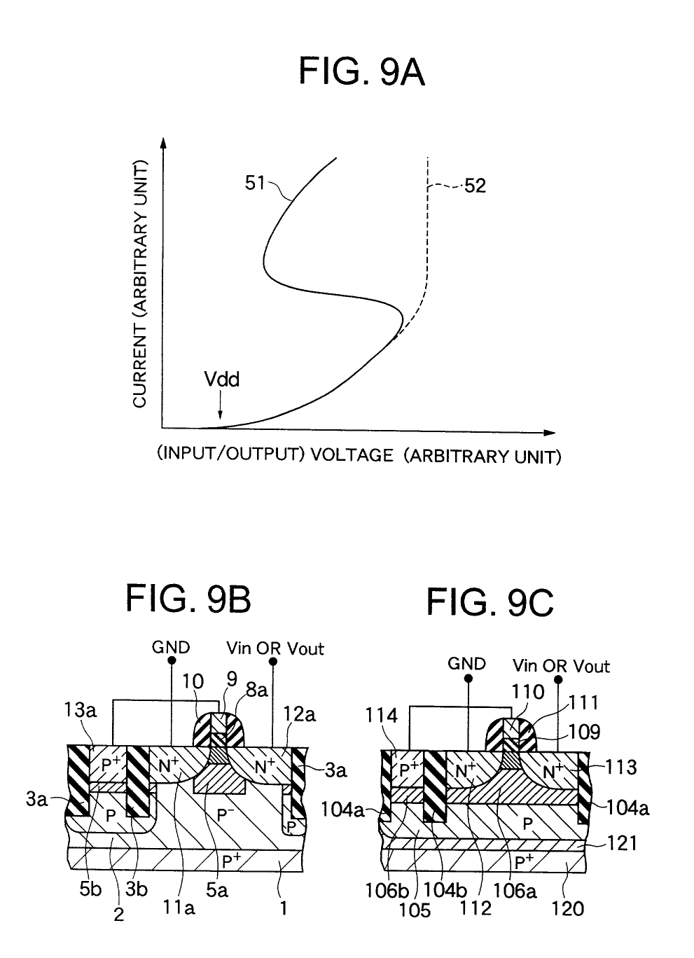

Next, the effect of the present invention will be explained. FIG. 9A is a graph showing a reverse tolerance voltage characteristic of nMOS of the CMOS in the embodiment by taking a voltage between the source and the drain of the nMOS on the horizontal axis while taking the a current between the source and the drain thereof on the vertical axis.

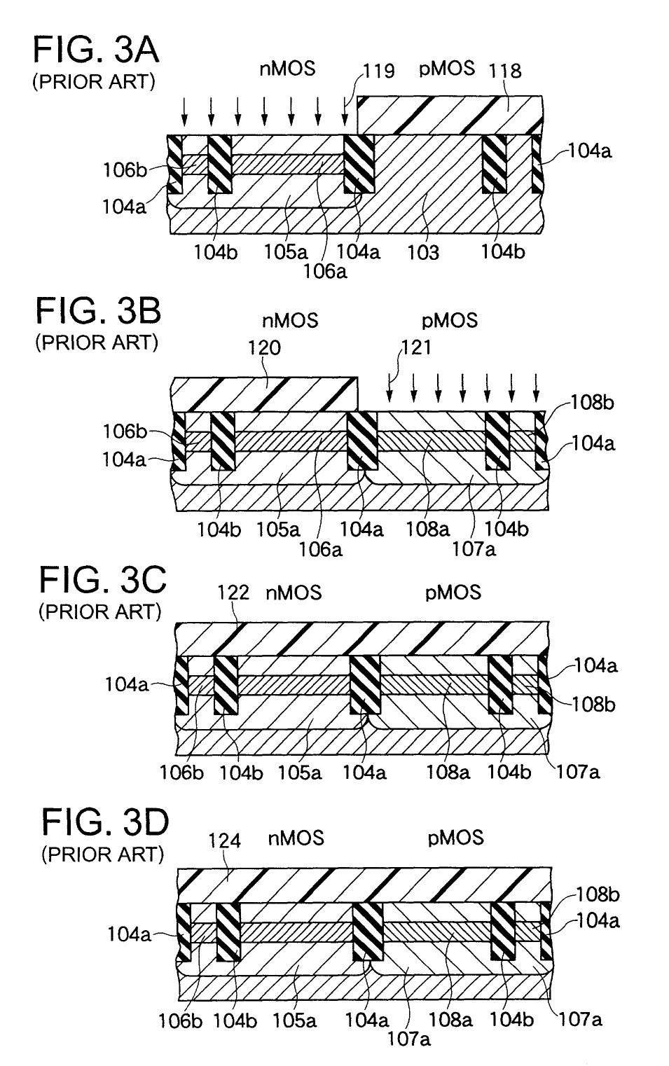

A method for measuring the tolerance voltage characteristic will be explained. FIGS. 9B and 9C are sectional views showing the semiconductor device according to the first embodiment and the prior art wherein the tolerance voltage characteristic is measured. Incidentally, the same constituent element of FIGS. 2 and 5 are denoted by the same reference numerals. The device shown in FIG. 9B has the same construction as the protection circuit portion of the present embodiment. That is, a silicon epitaxial layer 2 is formed on the high concentration silicon substrate 1. On a lower portion of the channel region of this silicon epitaxial layer 2, the P-type locally doped layer 5a is formed. Then, the gate electrode 9, the N-type source diffusion layer 11a and the P-type lead diffusion layer 13a are connected and grounded to GND so that a voltage (input/output voltage) is applied to the N-type drain diffusion layer 12a.

Furthermore, FIG. 9C is a view showing a case in which the p/p⁺ substrate is used for suppressing a latch-up of the internal circuit in the structure of the prior art shown in the drawing. That is, in a similar manner as FIG. 9B, a silicon epitaxial layer 121 is formed on the high concentration silicon substrate 120. Then, on the surface of the epitaxial layer 121, the P-type well layer 105a and the P-type channel doped layer 106a are subsequently formed in order. The other structure is the same as FIG. 9B.

As shown in FIG. 9A, in the MOS transistor of FIG. 9C in which the conventional p/p substrate is replaced with the p/p⁺ substrate, the drain current and the drain voltage characteristic 52 of the MOS transistor is shown only with respect to the avalanche breakdown of a normal PN junction, so that not snap back characteristic does not appear. In contrast, in the case of the embodiment, namely, in the case of the embodiment, a large snap characteristic is shown in the drain current and drain voltage characteristic 51 of the MOS transistor shown in FIG. 9B.

Next, there will be explained a mechanism in which a snap back phenomenon is generated in the embodiment. In the case where a large surplus surge current is input to the N-type drain region 12a, a reverse direction current of the PN junction flows between the N-type drain region 12a and the P-type locally doped layer 5a (or a silicon epitaxial layer 2). This current has passes through the N-type drain region 12a, the P-type locally doped layer 5a, the silicon epitaxial layer 2 and the high concentration silicon substrate 1 to the side of the p-type lead diffusion layer 13a. In this case, the silicon epitaxial layer 2 has a low concentration of 1×10¹⁵ cm⁻³ and a high resistance. Then, furthermore, the channel diffusion layer (P-type locally doped layer 5a) having a concentration of about 5×10¹⁷ cm⁻³ is selectively formed. Consequently, since current flows in a concentrated manner through a portion where the P-type locally doped layer 5a and the N-type drain diffusion layer 12a comes into contact with each other, the potential of the P-type locally doped layer 5a becomes high along with the flow of the current from the N-type drain region 12a to the P-type lead diffusion layer 13a. Then, when the potential of the P-type locally doped layer 5a is heightened to the about 0.6V, the N-type source diffusion layer 11a serves as an emitter, the P-type locally doped layer 5a serves as a base, and the N-type drain diffusion layer 12a serves as a collector so that the bipolar operation is generated and the snap back characteristic is observed.

On the other hand, in the MOS transistor shown in FIG. 9C in which the conventional p/p substrate is replaced with the p/p⁺ substrate, the reverse direction current of the PN junction flows through the N-type drain diffusion layer 113?the P-type channel doped layer 106a, the P-type well layer 105, the silicon epitaxial layer 121 and the high concentration silicon substrate 120 to the P-type lead diffusion layer. At this time, a high resistance silicon epitaxial layer 121 having an impurity concentration of about 1×10¹⁵ cm⁻³ is present only in the thickness between the P well 105 and the high concentration silicon substrate 120. Furthermore, a medium level resistance P well 105 having an impurity concentration of about 1×10¹⁷ cm⁻³ also functions only as a resistor for the portion of the thickness between the P-type channel doped layer 106a and high concentration silicon substrate 120 with the result that the entire resistor from the N-type drain diffusion layer 113 up to the P-type lead diffusion layer 114 is considerably lowered as compared with the case of the first embodiment. Consequently, the potential of the P-type channel doped layer 106a to be a base originally rises with difficulty with the result that a breakdown is generated between the N-type drain diffusion layer 113 and the P-type channel doped layer 106a before the generation of the bipolar transistor, namely, without generating the snap back operation thereby destroying the junction.

Incidentally, in the prior art shown in FIG. 2 wherein no p/p⁺ substrate is not used, current flows in a horizontal direction in the P-type well layer 105 having an intermediate level resistor. Consequently, a resistance is generated only for the width of the P-type well layer 105 with the result that the snap back operation is generated. However, as described above, a latch-up of the internal circuit is generated in the fine CMOS with the result that the transistor having the structure shown in FIG. 2 is not favorable.

In the MOS transistor of the present embodiment, in the case where the nMOS channel diffusion layer (the P-type locally doped layer) is selectively formed on a lower portion of the channel region and the p/p⁺ substrate is used, the protection function is extremely heightened by dispensing with the usage of the P well layer on the lower portion of the nMOS active region.

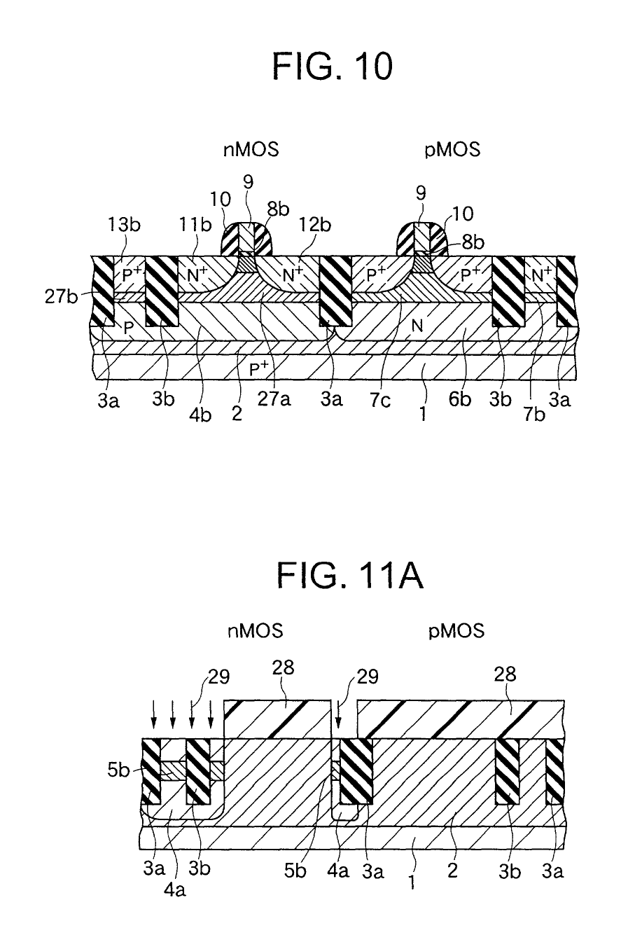

Next, a second embodiment of the present invention will be explained. In the second embodiment, the CMOS of the protection circuit portion is the same as the first embodiment, and the CMOS of the internal circuit portion differs. The second embodiment can be preferably used in the case where the semiconductor device is heightened in speed and the MOS transistor constituting the internal circuit portion is made further fine. Incidentally, in the second embodiment shown in FIGS. 10 through 12, the same constituent elements as the first embodiment shown in FIGS. 5 through 9 are denoted by the same reference numerals and a detailed explanation thereof is omitted.

In the same manner as the semiconductor device (a CMOS constituting a portion of the internal circuit) according to the first embodiment shown in FIG. 6 in the CMOS of the internal circuit of the present embodiment, a silicon epitaxial layer 2 is formed on the high concentration silicon substrate 1, and device isolation insulating films 3a and 3b are formed on the surface of the silicon epitaxial layer 2. As a consequence, the device active region is partitioned.

Then, the P well layer 4b is formed on the surface of the silicon epitaxial layer 2 on the entire surface of the nMOS device active region. Furthermore, the P-type channel doped layer 27 is formed in a band-like configuration on the entire region of the P well layer 4b. In a similar manner, the N well layer 6b is formed on the surface of the silicon epitaxial layer 2 on the entire surface of pMOS device active region, and the N-type channel doped layer 7c is formed in a band-like configuration in the entire region within the N well layer 6a. Then, the gate insulating film 8b, the gate electrode 9, the sidewall 10, the source and drain diffusion layers 11b, 14b, 12b, 15b and the like are formed in the same manner as FIG. 6 so that the CMOS is constituted. In this manner, according to the second embodiment, in the MOS transistor and the CMOS transistor constituting the internal circuit of the semiconductor device, the channel diffusion layers 27a and 27c are formed over the gate electrode and the entire surface of the lower region of the source diffusion layer and the drain diffusion layer.

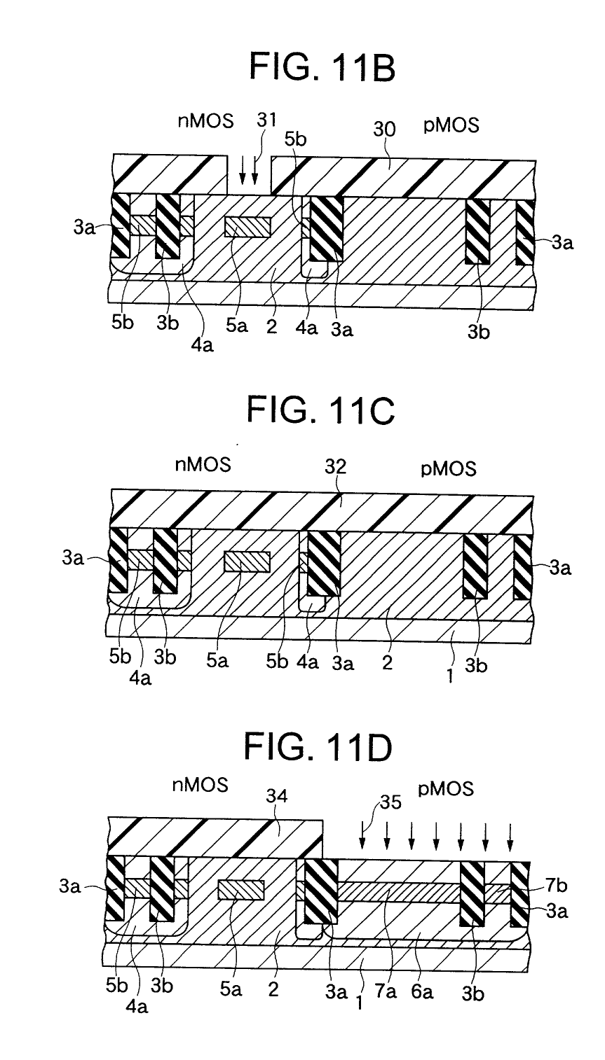

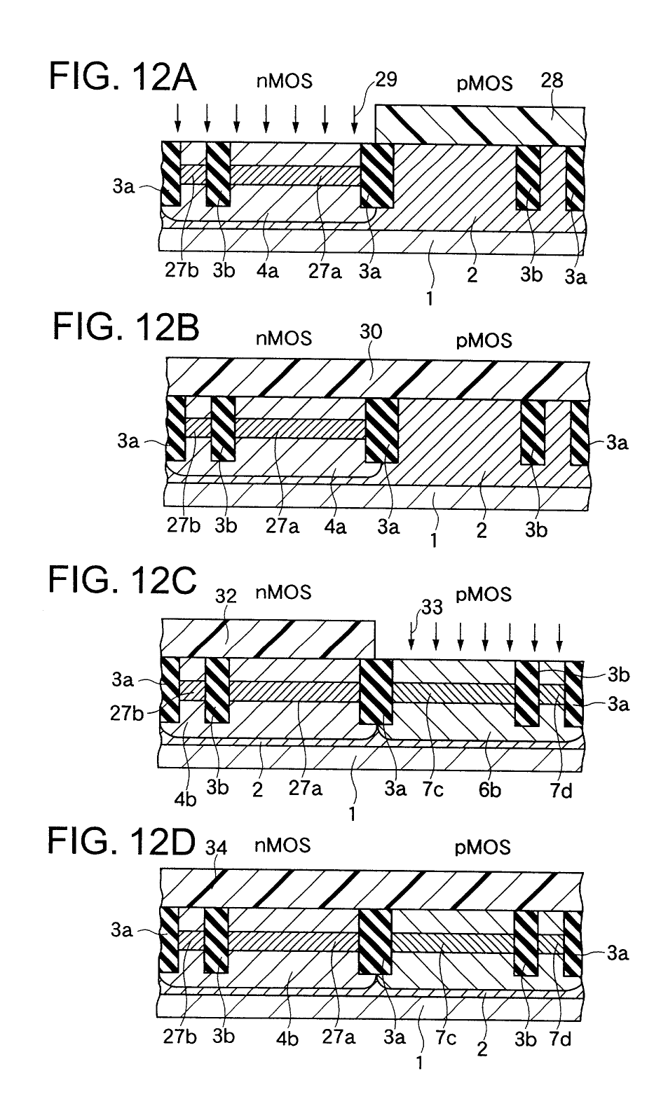

Next, there will be explained a method for manufacturing the CMOS of the protection circuit portion and the internal circuit portion of the present embodiment. FIGS. 11A through 11D are sectional views showing a method for manufacturing a CMOS of the protection circuit portion in order of steps according to the second embodiment of the present invention. FIGS. 12A through 12D are sectional views showing a method for manufacturing the CMOS of the internal circuit portion according to the second embodiment in the order of steps.

As shown in FIGS. 11A and 12A, in a similar manner as the first embodiment, a silicon epitaxial layer 2 having a thickness of 2 μm is formed on the high concentration silicon substrate 1. Here, the impurity concentration of the silicon epitaxial layer 2 is about 31×10¹⁵ atoms/cm³. Next, on the surface of the silicon epitaxial layer 2, the device isolation insulating films 3a and 3b are formed. Furthermore, a resist mask 28 is formed wherein a portion of the nMOS region of the protection circuit portion and the entire surface of the nMOS region of the internal circuit are opened. Boron 29 is continuously ion implanted twice by using the resist mask 28 as a mask. The first time boron ion implantation energy is, for example, 100KeV. The second time boron ion implantation energy is, for example, 20KeV. Next, by heat treatment, as shown in FIG. 11A, the P well layer 4a and the P-type doped layer 5b are formed on a portion of the nMOS region of the protection circuit portion. At the same time, as shown in FIG. 12A, on the entire surface of the nMOS region of the internal circuit portion, the P well layer 4a, the P-type channel doped layer 27a and the P-type doped layer 27b are formed. The impurity concentration of the P well layers 4a and 4b is, for example, 2×10¹⁷ atoms/cm³ while the impurity concentration of the P-type channel doped layer 27a, the P-type doped layer 27b is, for example, 2×10¹⁸ atoms/cm³.

Next, as shown in FIGS. 11B and 12B, the entire surface of the internal circuit portion is covered and a resist mask 30 is formed wherein only the nMOS channel region of the protection circuit portion is open. Then, boron 31 is ion implanted by using the resist mask 30 as a mask. The ion implantation energy is, for example, 20KeV while the dose amount is, for example, about 6×10¹² atoms/cm³. Next, heat treatment is conducted, and the P-type locally doped layer 5a is selectively formed which constitutes a channel diffusion layer on a region located at a lower portion of the nMOS channel region within the silicon epitaxial layer 2 of the protection circuit portion.

Next, as shown in FIGS. 11C and 12C, the entire surface of the protection circuit portion is covered and the nMOS region of the internal circuit portion is formed, and the resist mask 32 is formed wherein the pMOS region is open. Then, as shown in FIG. 12C, phosphorus and arsenic are ion implanted by using the resist mask 32 as a mask. In the first time ion implantation, phosphorus is ion implanted. This phosphorus ion implantation energy is, for example, 200KeV, and the dose amount is, for example, 1×10¹³ atoms/cm². Then, arsenic 33 is continuously ion implanted. The second time ion implantation energy is, for example, 70KeV while the dose amount is, for example, 7×10 ¹² atoms/cm². Next, heat treatment is conducted. In this manner, the N well layer 6b and the N-type channel doped layer 7c, and the N-type doped layer 7d are formed. The impurity concentration of the N well layer 6b is, for example, 2×10¹⁷ atoms/cm³. The impurity concentration of the N-type channel doped layer 7c and the N-type doped layer 7d is, for example, 2×10¹⁸ atoms/cm³.

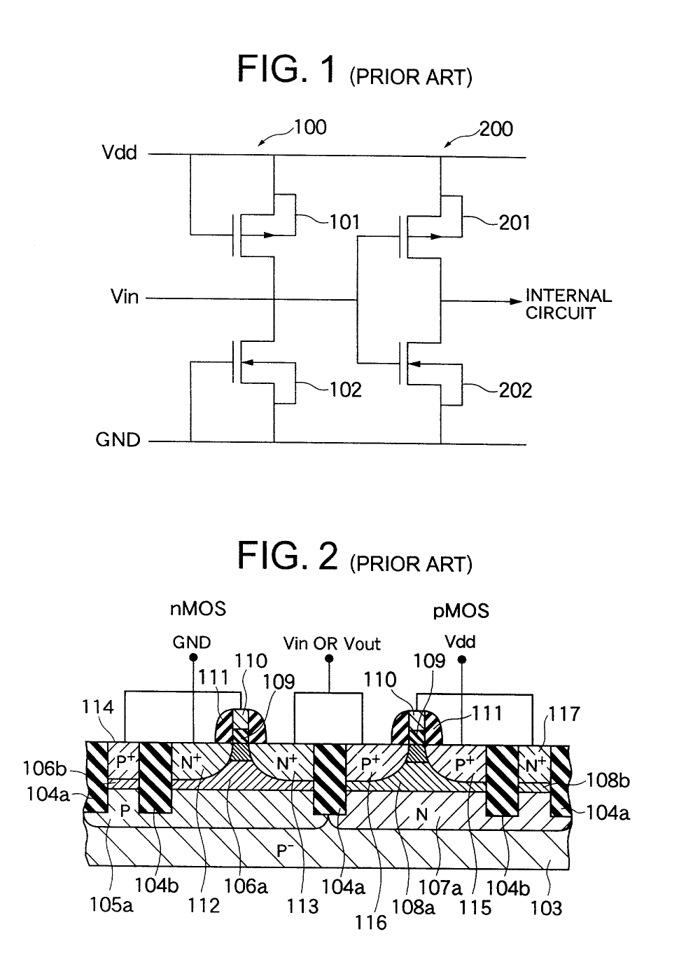

Next, in a similar manner, as shown in FIGS. 11D and 12D, the entire surface of the internal circuit is covered while the nMOS region of the outside circuit is covered. Thus, a resist mask 34 is formed wherein only the pMOS region is open. Then phosphorus and arsenic 35 is continuously ion implanted twice. Next, heat treatment is conducted to form the N well layer 6a and the N-type channel doped layer 7a and the N-type doped layer 7b on the protection circuit portion as shown in FIG. 1D. The impurity concentration of the N well layer 6a is, for example, 1×10¹⁷ atoms/cm³, and the impurity concentration of the N-type channel doped layer 7a and the N-type doped layer 7b is, for example, 5×10¹⁷ atoms/cm³.

Thereafter, in the same manner as the first embodiment, the gate insulating films 8a and 8b and the gate electrode 9 and the spacer 10 are formed. Furthermore, the source and drain diffusion layer and the lead diffusion layer of the nMOS and pMOS are provided to form the CMOS.

The thickness of the gate insulating film 8b of the internal circuit portion of the second embodiment is, for example, 1.5 nm in terms of the silicon oxide film while the gate length is, for example, 0.1 μm or less. Then, the thickness of the gate insulating film 8a of the protection circuit portion is, for example, about 4 nm in terms of the thickness of the silicon oxide film while the gate length is, for example, about 0.25 μm or less.

In addition, the depth of the P-type locally doped layer 5 is, for example, 0.10 μm. The depth of the N-well layers 6a, 6b is, for example, about 0.3 μm. The depth of the N-type channel doped layers 7a, 7b is, for example, about 0.19 μm. Further the depth of the source and drain diffusion layer and the lead diffusion layer is, for example, 0.1 μm or less.

In this embodiment, as shown in FIG. 9, the same effect as the first embodiment is provided while in the nMOS transistor of the internal circuit the P-type channel doped layer is formed on the entire surface of the transistor. Thus, the semiconductor device is further highly integrated so that the second embodiment becomes extremely effective in the case where the MOS transistor constituting the internal circuit portion becomes more fine. Furthermore, the photolithography step is fewer by one time than the first embodiment, and the productivity is further improved.

That is, the length of the source and drain region (distance from the device isolation region up to the channel region) also becomes short as the MOS transistor of the internal circuit becomes more and more fine. Consequently, the junction capacity (Cj) of the source and drain diffusion layer also becomes small. At this time, when a comparison is made between the case in which the channel doped layer is restricted and formed on the lower portion of the channel region in the same manner as the first embodiment and the case in which the channel doped layer is formed on the whole portion including the lower portion of the source and drain diffusion layer, the difference becomes smaller as the MOS transistor becomes more and more fine. Then, in the case where the semiconductor is made more fine, an attempt is made to decrease the number of steps by forming a channel doped layer on a whole region including the lower portion of the source and drain diffusion layer to decrease the photolithography step by one step rather than providing one step of the photolithography step to slightly improve Cj and to attain improved productivity thereby the more advantageous effect can be obtained.

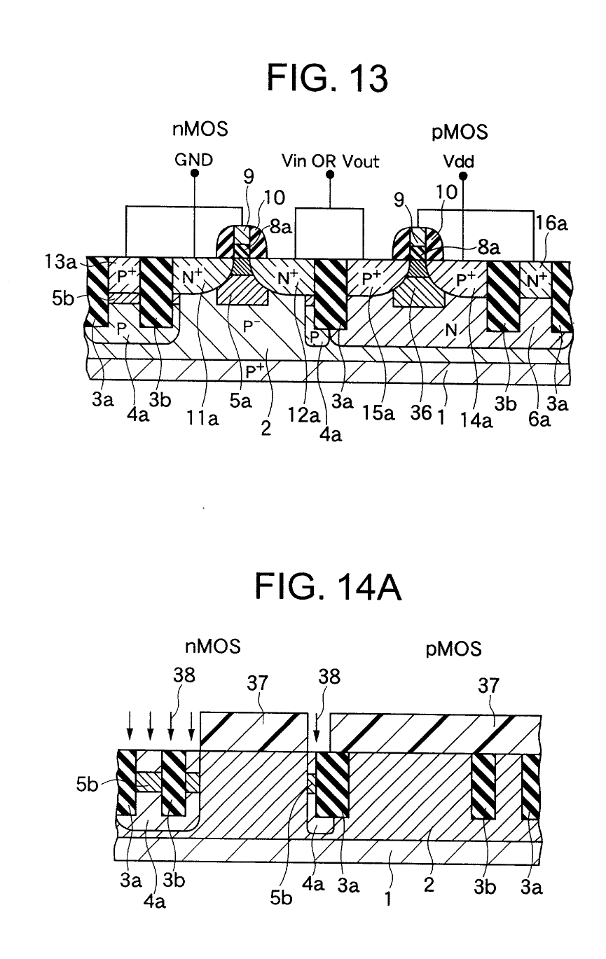

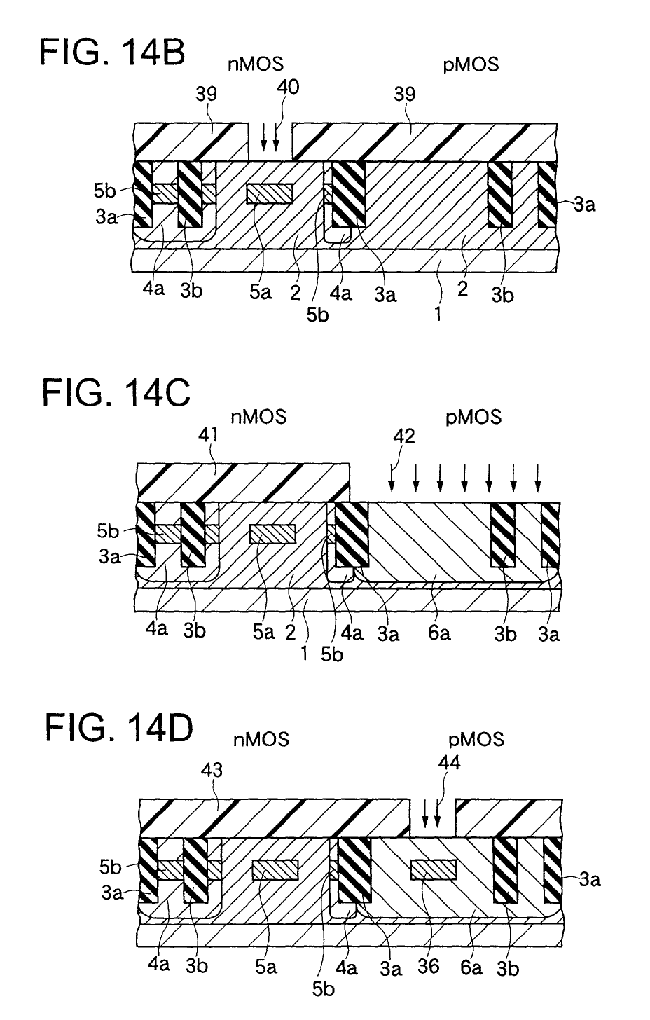

Next, a third embodiment of the present invention will be explained. FIG. 13 is a sectional view showing a semiconductor device (a CMOS inverter of the protection circuit portion) according to the third embodiment. In the third embodiment, a locally doped layer is formed on the pMOS in the same manner as the case of the nMOS. Furthermore, since the internal circuit portion can be constituted in the same structure as the first embodiment and the second embodiment, an explanation of the CMOS and the manufacturing method thereof is omitted. Incidentally, in the third embodiment shown in FIGS. 13 and 14, the same constituent elements as the first embodiment shown in FIGS. 5 through 9 are denoted by the same reference numerals. A detailed explanation thereof is omitted.

As shown in FIG. 13, in the CMOS inverter of the protection circuit according to the third embodiment, a silicon epitaxial layer 2 having a thickness of about 2 μm is formed on the high concentration silicon substrate 1. Then, on the surface of the silicon epitaxial layer 2, the device isolation films 3a and 3b are formed so that the device active region is partitioned. Then, in the nMOS device active region, in the same manner as the first embodiment, the P well layer 4a is formed so that the P-type locally doped layer 5a is selectively formed on a region located at a lower portion of the nMOS channel region in the silicon epitaxial layer 2. Furthermore, in the nMOS active region, on the entire surface of the silicon epitaxial layer 2, the N well layer 6a is formed and the N-type locally doped layer 36 which is a channel diffusion layer is selectively formed on the region located at a lower portion of the pMOS channel region which is the N well layer 6. The other structure is the same as the first embodiment.

Next, a method for manufacturing the semiconductor device (a CMOS inverter of the protection circuit portion) according to a third embodiment of the present invention will be explained. FIGS. 14A through 14D are sectional views showing a method for manufacturing the CMOS inverter of the protection circuit portion of the third embodiment in the order of steps.

As shown in FIG. 14A, the silicon epitaxial layer 2 is formed which has a thickness of 2 μm on the high concentration silicon substrate 1. Here, the impurity concentration of the silicon epitaxial layer 2 is about 2×10¹⁵ atoms/cm³. Then, the device isolation insulating film 3a and 3b are formed on the surface of the silicon epitaxial layer 2. Next, a resist mask 37 is formed where a portion of the nMOS region is open. Boron 38 is ion implanted continuously twice to the mask to form the P well layer 4a of the protection circuit portion, and P-type doped layer 5b.

Next, as shown in FIG. 14B, a resist mask 39 is formed wherein only the channel formation region of the MOS transistor is open. Here, boron 40 is ion implanted by using the resist mask 39 as a mask. Here, the ion implantation energy is, for example, 20KeV while the dose amount is, for example, 6×10¹² atoms/cm². Next, heat treatment is conducted, and the P-type locally doped layer 5a is selectively formed on a region located at a lower portion of the nMOS channel region within the silicon epitaxial layer 2 of the protection circuit portion.

Next, as shown in FIG. 14C, the entire surface of the nMOS region is covered, and a resist mask 41 is formed wherein only the pMOS region is open. Then, phosphorus 42 is ion implanted by using the resist mask 41 as a mask. Here, the phosphorus ion implantation energy is, for example, 200KeV, and the dose amount is, for example, about 1×10¹³ atoms/cm². Thereafter, heat treatment is conducted, and the N well layer 6a is formed.

Next, as shown in FIG. 14D, a resist mask 43 is formed in which only the channel formation region of the pMOS region is open. Then, arsenic 44 is ion implanted by using the resist mask 43 as a mask. This ion implantation energy is, for example, 70KeV, and the dose amount is, for example, about 5×10¹² atoms/cm². Next, heat treatment is conducted so that the N-type locally doped layer 36 is formed in the N well layer 6a. Thereafter, in the same manner as the first embodiment, the gate electrode, the source and drain diffusion layer, and the lead diffusion layer and the like are formed.

The depth of the P-type locally doped layer 5a and the N-type locally doped layer 36 according to the third embodiment is, for example, about 0.10 μm. Furthermore, the depth of the N well layer 6a is, for example, about 0.3 μm. The depth of each of the diffusion layer is, for example, 0.1 μm or less.

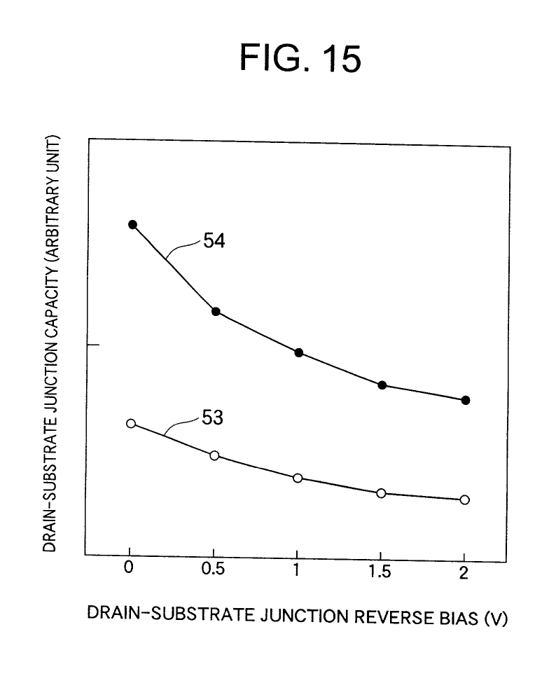

Next, the effect of the present invention will be explained. FIG. 15 is a graph showing a parasitic capacity of a junction between the N-type drain diffusion layer and the substrate (corresponding to the silicon epitaxial layer or the P well layer) in the nMOS constituting the protection circuit portion of the third embodiment. Incidentally, the input and output circuit or the protection circuit is assumed. The gate length of the MOS transistor is 0.35 μm and the gate width is 200 μm. Furthermore, the width of the source and drain diffusion layer is 1 μm. The impurity concentration or the depth of the diffusion layer is the same as the first embodiment or the prior art.

The horizontal axis of FIG. 15 shows a reverse bias applied between the drain diffusion layer and the substrate, the bias ranging a value of 0V through 2V. Then, the vertical axis shows the junction capacity at that time. As shown in FIG. 15, in the present embodiment, the parasitic capacity 53 is decreased to the ½ to ⅓ of the parasitic capacity 54 of the prior art. This is because the channel diffusion layer and the drain diffusion layer are formed so that the channel diffusion layer and the drain diffusion layer are overlapped on the entire surface thereof in the prior art whereas the locally doped layer corresponding to the channel diffusion layer is selectively formed at the lower potion of the channel region in the embodiment and an area where the locally doped layer and the drain diffusion layer are overlapped is largely decreased. In the embodiment, the parasitic capacity is decreased in pMOS in the same manner both in the first embodiment and the second embodiment. The parasitic capacity of nMOS is decreased in the same manner also in the case where the channel diffusion layer is selectively formed.

The consumed power at the protection circuit portion can be largely decreased by decreasing the parasitic capacity of the junction in this manner. Furthermore, the operation speed of the protection circuit portion can be improved by decreasing the parasitic capacity.

Furthermore, in the third embodiment, in the CMOS of the internal circuit portion of the semiconductor device, the channel diffusion layer is locally formed in the same manner as the nMOS transistor of the first embodiment, the parasitic capacity can be decreased though the above effect is somewhat inferior to the effect of decreasing the parasitic capacity of the protection circuit portion.

Furthermore, in the first to the third embodiments, the protection of the semiconductor device from the ESD breakage which is assumed to take place many times from now on is secured, and the realization of the semiconductor device is promoted which will be extremely highly integrated and which will be extremely increased in speed. Furthermore, it is also possible to secure a high reliability and a high yield ratio of the semiconductor device.

Incidentally, with respect to the first to the third embodiments, an explanation is made on the case in which the semiconductor device is formed on the p/p⁺ epitaxial layer. However, the present invention can be also applied to the case in which the semiconductor device is formed on a normal bulk substrate. Furthermore, in the case where the conductive type of the silicon substrate is reversed, the present invention can be applied in the same manner.

Furthermore, the present invention is not limited to the above embodiments, and the embodiments are appropriately modified within the scope of the technical concept of the present invention.

What is claimed is:

1. A semiconductor device comprising:
a semiconductor substrate;
a gate insulating film formed at a predetermined portion on the semiconductor substrate and a gate electrode formed on the gate insulating film;
source and drain diffusion layers formed at the surface of the semiconductor substrate at portions sandwiching a channel region under the gate electrode; and
a channel diffusion layer having a conductive type reverse to the source and drain diffusion layers and a higher impurity concentration than the semiconductor substrate, the channel diffusion layer being selectively formed at a lower portion of the channel region to be connected to the source and drain diffusion layers.

2. A semiconductor device comprising:
a semiconductor substrate;
an epitaxial layer having the same conductive type as the semiconductor substrate and a lower impurity concentration than the semiconductor substrate, the layer being formed on the semiconductor substrate;
a gate insulating film formed at a predetermined portion on the epitaxial layer, and a gate electrode formed on the gate insulating film;
source and drain diffusion layers formed at the surface of the epitaxial layer at portions sandwiching a channel region under the gate electrode; and
a channel diffusion layer having a conductive type reverse to the source and drain diffusion layers and a higher impurity concentration than the epitaxial layer, the channel diffusion layer being selectively formed at a lower portion of the channel region to be connected to the source and drain diffusion layers.

3. A semiconductor substrate comprising:
a semiconductor substrate;
a well layer having a conductive type reverse to the semiconductor substrate, the layer being formed on the surface of the semiconductor substrate;
a gate insulating film formed at a predetermined portion on the well layer and a gate electrode formed on the gate insulating film;
source and drain diffusion layers formed at the surface of the well layer at portions sandwiching a channel region under the gate electrode; and
a channel diffusion layer having a conductive type reverse to the source and drain diffusion layers and a higher impurity concentration than the well layer, the channel diffusion layer being selectively formed at a lower portion of the channel region to be connected to the source and drain regions.

4. A semiconductor device comprising:
a semiconductor substrate of a first conductive type;
a well layer of a second conductive type selectively formed on the surface of the semiconductor substrate;
a first gate insulating film formed at a predetermined portion on the semiconductor substrate and a first gate electrode formed on the first gate insulating film;
a second gate insulating film formed at a predetermined portion on the well layer and a second gate electrode formed on the second gate insulating film;
first source and drain diffusion layers of a first conductive type formed at the surface of the semiconductor substrate at portions sandwiching a channel region under the first gate electrode;
second source and drain diffusion layers of a second conductive type formed at the surface of the well layer at portions sandwiching a channel region under the second gate electrode;
a first channel diffusion layer of a second conductive type having a higher impurity concentration than the semiconductor substrate, the first channel diffusion layer being selectively formed at a lower portion of the channel region to be connected to the first source and drain diffusion layers; and
a second channel diffusion layer of a first conductive type having a higher impurity concentration than the well layer, the second channel diffusion layer being formed at an entire region between the second source and drain diffusion layers so as to be connected to the second source and drain diffusion layers at a lower portion of the channel region.

5. A semiconductor device comprising:
a semiconductor substrate of a first conductive type;
a well layer of a second conductive type selectively formed on the surface of the semiconductor substrate;
a first gate insulating film formed at a predetermined portion on the semiconductor substrate and a first gate electrode formed on the first gate insulating film;
a second gate insulating film formed at a predetermined portion on the well layer and a second gate electrode formed on the second gate insulating film;
first source and drain diffusion layers of a first conductive type formed at the surface of the semiconductor substrate at portions sandwiching a channel region under the first gate electrode;
second source and drain diffusion layers of a second conductive type formed at the surface of the well layer at portions sandwiching a channel region under the second gate electrode;
a first channel diffusion layer of a second conductive type having a higher impurity concentration than the semiconductor substrate, the first channel diffusion layer being selectively formed at a lower portion of the channel region to be connected to the first source and drain diffusion layers; and
a second channel diffusion layer of a first conductive type having a higher impurity concentration than the well layer, the second channel diffusion layer being selectively formed at a lower portion of the channel region to be connected to the second source and drain diffusion layers.

6. A method for manufacturing a semiconductor device comprising the steps of:
forming a channel diffusion layer having a higher impurity concentration than the semiconductor substrate on a lower portion of a region which constitutes a channel by selectively ion implanting a first conductive type of impurity between a region where a source diffusion layer on the first conductive type semiconductor substrate is to be formed and a region where a drain diffusion layer is to be formed thereon;
subsequently forming a gate insulating film and a gate electrode on the gate insulating film on the semiconductor substrate above the channel diffusion layer; and
forming a source diffusion layer and a drain diffusion layer by ion implanting a second conductive type of impurity on the surface of the semiconductor substrate at a location sandwiching the gate electrode.

7. A method for manufacturing a semiconductor device comprising the steps of:
forming a well layer by ion implanting a second conductive type of impurity on the surface of the first conductive type of the semiconductor substrate;
forming a channel diffusion layer having a higher impurity concentration than the well layer at a lower portion of the region which constitutes a channel by the selective ion implantation of the second conductive type of impurity between a region where the source diffusion layer of the well layer is to be formed and a region where a drain diffusion layer is to be formed thereon;
subsequently forming a gate insulating film and a gate electrode on the gate insulating film on the well above the channel diffusion layer; and
forming a source diffusion layer and a drain diffusion layer by the ion implantation of the first conductive type of impurity on the surface of the well layer at a location sandwiching the gate electrode.

8. A method for manufacturing a semiconductor device, comprising the steps of:
forming the well layer and a channel diffusion layer having a higher impurity concentration than the well layer on the entire region of the well layer on a lower portion of the region which constitutes a channel of a first MOS transistor by selectively ion implanting a plurality of times a second conductive type of impurity on the first MOS transistor formation region on the surface of the first conductive type semiconductor substrate;
forming a channel diffusion layer having a higher impurity concentration than the semiconductor substrate on a lower portion of the region which constitutes a channel of a second MOS transistor by selectively ion implanting the first conductive type of impurity between the region where the source diffusion layer of the second MOS transistor formation region is to be formed on the surface of the semiconductor substrate and the region where the drain diffusion layer is to be formed;
subsequently forming a gate insulating film of the first MOS transistor and the second MOS transistor and a gate electrode on the gate insulating film respectively on the well layer of the region which constitutes a channel of the first MOS transistor and the second MOS transistor and on the semiconductor substrate;
forming the source diffusion layer and the drain diffusion layer of the first MOS transistor by ion implanting the first conductive type of impurity on the surface of the well layer at a location sandwiching the gate electrode of the first MOS transistor; and
forming the source diffusion layer and the drain diffusion layer of the second MOS transistor by ion implanting the second conductive type of impurity on the surface of the well layer at a location sandwiching the gate electrode of the second MOS transistor.

9. The method for manufacturing the semiconductor device according to claim 7, comprising the steps of:
forming a well layer by selectively ion implanting a second conductive-type of impurity on the surface of the first conductive type of the semiconductor substrate;
forming a channel diffusion layer having a higher impurity concentration than the well layer on a lower portion of the region which constitutes a channel by selectively ion implanting the second type of impurity between the region where the source diffusion layer of the well layer is to be formed and the region where the drain diffusion layer is to be formed;
subsequently forming a gate insulating film on the well layer of the region which constitutes the channel and a gate electrode on the gate insulating film; and
forming the source diffusion layer and the drain diffusion layer by ion implanting the first conductive type of impurity on the surface of the well layer at a location sandwiching the gate electrode.
